(19) United States
(12) Patent Application Publication
(10) Pub. No.: US 2021/0222321 A1
(43) Pub. Date: Jul. 22, 2021

(54) METHOD FOR GROWING SINGLE CRYSTAL

(71) Applicant: SHIN-ETSU HANDOTAI CO., LTD., Tokyo (JP)

(72) Inventors: Ryoji HOSHI, Nishigo-mura (JP); Keisuke MIHARA, Nishigo-mura (JP); Kousei SUGAWARA, Nishigo-mura (JP); Suguru MATSUMOTO, Nishigo-mura (JP)

(73) Assignee: SHIN-ETSU HANDOTAI CO., LTD., Tokyo (JP)

(21) Appl. No.: 17/269,197

(22) PCT Filed: Jun. 10, 2019
(86) PCT No.: PCT/JP2019/022847

§ 371 Date: Feb. 17, 2021

(30) Foreign Application Priority Data
Aug. 29, 2018 (JP) 2018-160522

(51) Int. Cl. C30B 15/00; C30B 29/06

(52) U.S. Cl. CPC C30B 15/00; C30B 29/06

(57) ABSTRACT

A method for growing a single crystal according to a Czochralski method (CZ method) or a magnetic field applied CZ method (MCZ method), the method including: a first step of obtaining a melt by melting a silicon raw material loaded in a crucible; a second step of forming a solidified layer by solidifying a part of the melt; a third step of removing at least a part of the melt in a state where the solidified layer and the melt coexist; a fourth step of obtaining a melt by melting the solidified layer; and a fifth step of growing a silicon single crystal from the melt. Consequently, a method for purifying a silicon raw material and growing a single crystal on one CZ pulling apparatus and growing a single crystal with a reduced impurity concentration is provided.

### TECHNICAL FIELD

The present invention relates to: a method for growing a single crystal according to a Czochralski method (CZ method) or a magnetic field applied CZ method (MCZ method).

### BACKGROUND ART

RF (radio frequency) devices are used as devices for communication such as mobile phones. In RF devices that use a silicon single crystal wafer, loss due to high conductivity becomes great if the resistivity of a substrate is low. Therefore, a wafer with a high resistivity of 1000 Ωcm or more, that is, a wafer with an extremely low dopant concentration of boron (B), phosphorous (P), or the like concerned with resistivity is used. A wafer called SOI (Silicon on Insulator) having a thin oxide film and a thin silicon layer formed on a surface layer of a silicon substrate is sometimes used, and high resistivity is also desired in this case.

In addition, for use as power devices, a wafer with a relatively high resistivity is desired for high breakdown voltage. Moreover, for IGBT and the like, a silicon single crystal with an extremely low carbon concentration has come to be required in order to obtain favorable characteristics.

As described, reduction of impurities such as dopants and carbon, being a light element, not to mention impurities such as heavy metal is an essential problem in the latest semiconductor devices.

In a CZ method, which is widely used to obtain a silicon single crystal, a single crystal is grown by melting a high-purity polycrystalline silicon called semiconductor grade in a quartz crucible, bringing a seed crystal into contact thereto, and pulling. Generally, a seed crystal is sliced from a grown single crystal, and an obtained single crystal has a relatively high purity since impurities are reduced by segregation during single crystal growth. The main factors of impurities in this case include the quartz crucible and the polycrystalline silicon.

Conventionally, a natural quartz crucible using a natural powder has been mainstream as the quartz crucible, but at present, a hybrid quartz crucible having a synthetic quartz layer made from a synthetic quartz powder formed on the inside thereof has become the mainstream (for example, Patent Document 1, etc.) and high resistivity and low-concentration dopants have also become achievable in the CZ method.

Meanwhile, the raw material polycrystalline silicon is mainly manufactured by a Siemens method or the like, and dopants and carbon are contained in polycrystalline silicon as impurities. For example, as disclosed in Patent Document 2, efforts are being made to reduce these impurities, and there is daily improvement.

On the other hand, in solar cells and the like, a low grade raw material is often used, and a technique for reducing impurities while manufacturing the product is reported. For example, Patent Document 3 and Patent Document 4 disclose reduction of impurities by a unidirectional solidification method where solidification is performed upwards from the bottom of the mold, in order to improve the quality and reduce distortion of the manufactured polycrystalline silicon. Since silicon has a higher density as a liquid than as a solid like water, the solid floats in the liquid when a melt is solidified. Therefore, silicon is liable to solidify from the surface. If solidification occurs from the surface, there is risk of the container breaking due to volume expansion when the melt surrounded by the solidified layer on the surface and the container changes to a solid. However, in these techniques, unidirectional solidification is performed upwards from the bottom of the mold by controlling the temperature.

Patent Document 5 discloses controlling oxygen concentration distribution by performing a DLCZ method of forming a solidified layer at the bottom of the crucible during a single crystal growth by a CZ method to suppress elution of oxygen from the crucible. Besides this, as a DLCZ method in single crystal growth, a technique for controlling resistivity is disclosed, and a technique of controlling the impurity concentration of a single crystal by forming a solidified layer at the bottom of the crucible is also disclosed in single crystal growth technology. However, these are not techniques for reducing impurities that have become mixed in the melt.

Meanwhile, Patent Document 6, Patent Document 7, and Patent Document 8 disclose techniques of raising the purity of a polycrystalline silicon by forming a solidified layer halfway and removing the melt.

### CITATION LIST

### Patent Literature

### Patent Document 1: JP H5-58788 A

### Patent Document 2: JP 2013-256431 A

### Patent Document 3: JP 2002-80215 A

### Patent Document 4: JP 2002-308616 A

### Patent Document 5: JP S62-153191 A

### Patent Document 6: WO 2010/018831 A1

### Patent Document 7: JP 2010-538952 A

### Patent Document 8: JP 2010-534614 A

### SUMMARY OF INVENTION

### Technical Problem

In a CZ method, carbon impurity, for example, may become mixed in from a carbon component used in a pulling apparatus while melting a raw material or growing a crystal, and various efforts have been made to reduce this in the long history of the CZ method. Meanwhile, it has long been known that oxygen impurity is an element that is eluted from a quartz crucible, and a part thereof is taken into the single crystal, greatly influencing device characteristics. Hence, control of oxygen concentration has also been long performed.

However, regarding impurities other than carbon impurity derived from components of the apparatus and oxygen impurity derived from the quartz crucible, a semiconductor-grade high-purity raw material is generally used, and purification is sometimes performed by segregation at the time of single crystal growth, and reduction of impurities has hardly been performed in the process of the CZ method itself.

In the current CZ method, reduction of impurities and control of impurities that result from raw materials such as polycrystalline silicon and quartz crucible is a problem, and the present condition is that this largely depends on technology for reducing the impurities in the raw materials and quartz crucible themselves.

For example, although the above-described Patent Document 8 discloses achievement of the purification of a polycrystalline silicon, purification of a single crystal silicon is not disclosed. Consequently, in order to attempt the purification of a single crystal silicon by these techniques, it is necessary to take out a polycrystalline silicon obtained by the technique disclosed in the Patent Document 8 as a raw material, and to prepare a different pulling apparatus for single crystallization, for example, and this is not practical.

As described above, reduction of impurity concentrations by improvement of a pulling process according to the CZ method has hitherto not been considered. Accordingly, an object of the present invention is to provide a method for purifying a silicon raw material (polycrystalline silicon) and growing a single crystal on one CZ pulling apparatus and growing a single crystal with a reduced impurity concentration.

### Solution to Problem

The present invention has been made to achieve the above-described object, and provides a method for growing a single crystal according to a Czochralski method (CZ method) or a magnetic field applied CZ method (MCZ method), the method comprising:

a first step of obtaining a melt by melting a silicon raw material loaded in a crucible;

a second step of forming a solidified layer by solidifying a part of the melt;

a third step of removing at least a part of the melt in a state where the solidified layer and the melt coexist;

a fourth step of obtaining a melt by melting the solidified layer; and

a fifth step of growing a silicon single crystal from the melt.

According to such a method for growing a single crystal, a single crystal with an extremely low impurity concentration (high purity) can be grown.

In this event, a sixth step of adding a silicon raw material into the crucible can be performed after the third step and before the fourth step in the method for growing a single crystal.

In this manner, a single crystal with a low impurity concentration (high purity) can be grown while maintaining the length (suppressing a drop in yield) of the single crystal that can be grown.

In this event, after the third step and before the fourth step,

a sixth step of adding a silicon raw material into the crucible,

the fourth step,

the first step,

the second step, and

the third step can be performed once or more in this order in the method for growing a single crystal.

In this manner, a single crystal with an even lower impurity concentration (higher purity) can be grown.

In this event, a formation ratio of the solidified layer in the second step can be 10% or more to 99% or less based on weight relative to the raw material initially loaded in the first step in the method for growing a single crystal.

In this manner, a longer single crystal can be grown and the yield can be raised, while at the same time, the formation ratio of the solidified layer can be controlled more simply and conveniently, and precision of the amount of melt to be removed can be raised.

In this event, in the third step, the melt of silicon can be removed by suction by using a suction apparatus equipped with a nozzle in the method for growing a single crystal.

In this manner, the melt can be removed more simply and conveniently.

In this event, in the second step, a formation ratio of the solidified layer can be detected by a change in melt level attributable to a difference in densities of solid and liquid in the method for growing a single crystal.

In this manner, it becomes possible to grasp and control the formation ratio of the solidified layer more simply, conveniently, and accurately.

In this event, a semiconductor-grade high-purity raw material can be used as the silicon raw material in the method for growing a single crystal.

In this manner, a single crystal with a lower impurity concentration (higher purity) can be grown.

### Advantageous Effects of Invention

As described above, it becomes possible to grow a single crystal with an extremely low impurity concentration (high purity) according to the inventive method for growing a single crystal.

### BRIEF DESCRIPTION OF DRAWINGS

FIG. 1 shows a conceptual diagram showing an outline of the method for growing a single crystal according to the present invention.

FIG. 2 shows a flow diagram of the first embodiment of the method for growing a single crystal according to the present invention.

FIG. 3 shows a flow diagram of the second embodiment of the method for growing a single crystal according to the present invention.

FIG. 4 shows a flow diagram of the third embodiment of the method for growing a single crystal according to the present invention.

FIG. 5 shows the calculated values of carbon concentration in a case where all the melt is removed.

FIG. 6 shows the calculated values of carbon concentration in a case where a part of the melt is removed.

### DESCRIPTION OF EMBODIMENTS

Hereinafter, the present invention will be described in detail. However, the present invention is not limited thereto.

As described above, a method for purifying a silicon raw material and growing a single crystal on one CZ pulling apparatus and growing a single crystal with a reduced impurity concentration has been desired.

The present inventors have earnestly studied the problems and found out that a method for growing a single crystal according to a Czochralski method (CZ method) or a magnetic field applied CZ method (MCZ method), the method including: a first step of obtaining a melt by melting a silicon raw material loaded in a crucible; a second step of forming a solidified layer by solidifying a part of the melt; a third step of removing at least a part of the melt in a state where the solidified layer and the melt coexist; a fourth step of obtaining a melt by melting the solidified layer; and a fifth step of growing a silicon single crystal from the melt makes it possible to grow a single crystal with an extremely low impurity concentration (high purity), and completed the present invention.

Hereinafter, an explanation will be given with reference to the drawings.

### First Embodiment

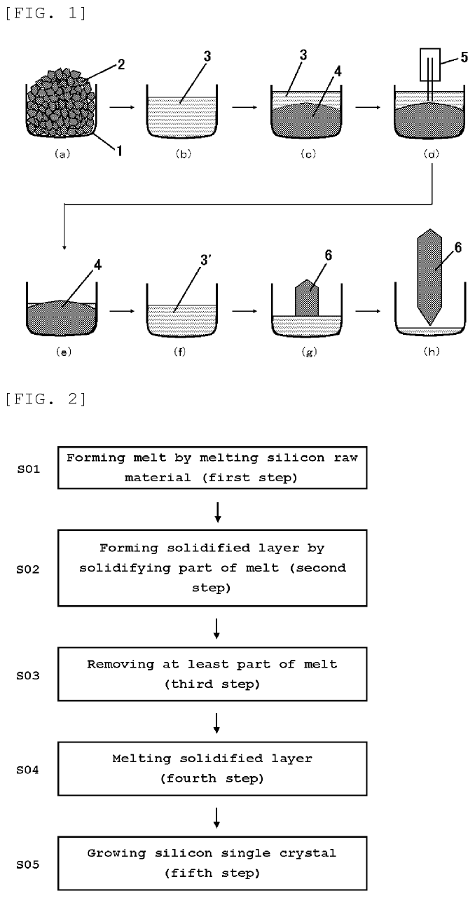

A conceptual diagram of the method for growing a single crystal according to the present invention is shown in FIG. 1, and a process flow thereof is shown in FIG. 2.

FIG. 1 (a) shows a state where polycrystalline silicon, being a silicon raw material 2, is loaded in a crucible 1.

After loading the silicon raw material 2 into the crucible 1, the silicon raw material 2 is heat-melted to form a melt 3 inside the crucible as shown in FIG. 1 (b). This step will be referred to as a first step (S01 in FIG. 2).

Next, as shown in FIG. 1 (c), a part of the melt 3 formed inside the crucible 1 is solidified to form a solidified layer 4. This step will be referred to as a second step (S02 in FIG. 2). In this manner, a state where the solidified layer 4 and the melt 3 coexist is achieved inside the crucible 1. Note that the solidified layer 4 can be formed by controlling a heating means (not shown) disposed around the crucible 1.

In this manner, when the silicon raw material 2 loaded in the crucible 1 is once melted, and then the solidified layer 4 is formed, the impurity concentration in the solidified layer 4 becomes lower than the concentration in the melt 3 due to segregation. As the solidification ratio progresses, the impurity concentration in the melt 3 becomes higher.

Note that the advantageous effects of the present invention can be achieved no matter how the solidified layer 4 is formed, but it is desirable to form the solidified layer 4 from the bottom of the crucible 1 as shown in FIG. 1 (c). In this way, the crucible 1 can be expected to have a longer life. Note that, although silicon is liable to solidify from the surface since the density of liquid is higher than solid, the solidified layer 4 can be formed from the bottom of the crucible 1 by employing the methods disclosed in the above-described Patent Documents 3 to 5 or the like. The solidified layer 4 that has grown from the bottom of the crucible 1 does not float since buoyancy does not work unless the melt 3 comes in between the solidified layer 4 and the bottom of the crucible 1.

At this point, segregation and solidification ratio will be briefly explained. When a silicon melt is solidified (crystallized), impurities in the melt are not easily taken into the crystal. The concentration ratio of the impurities that are taken into the crystal relative to the impurity concentration in the melt in this event is called a segregation coefficient “k”. Accordingly, the impurity concentration Cₛ in the crystal at a particular moment has the relation Cₛ=k×C_{L} with the impurity concentration C_{L} in the melt at that moment. “k” is generally a value smaller than 1, and therefore, the concentration of the impurities that are taken into the crystal is lower than the impurity concentration in the melt. Since crystal growth is performed continuously, a large amount of impurity is left in the melt, and the impurity concentration in the melt becomes gradually higher. Along with this, the impurity concentration in the crystal also becomes higher. Using the solidification ratio “x” showing, by ratio, the weight of the crystallized melt relative to the weight of the initial raw material and the impurity concentration C_{L0} in the initial melt, the concentration can be expressed as

Cₛ(x)=C_{L0}·k·(1−x)^{(k-1)}.

Consequently, the impurity concentration in the melt after solid formation or crystal growth is 1/k times as high as the concentration of the part that solidified or crystallized last. For example, in the case of carbon atoms, the segregation coefficient “k” is 0.07. This means that the carbon concentration in the melt is ten-odd times as much as the concentration in the crystal. In addition, the higher the solidification ratio, the higher the proportion of the impurities that are not taken into the crystal and remain to the weight of the melt. By employing such a segregation phenomenon, it is possible to raise the impurity concentration in the melt while keeping the impurity concentration in the solidified layer or the crystal low.

Here, in the second step, the formation ratio of the solidified layer 4 relative to the raw material initially loaded in the first step is preferably 10% or more to 99% or less based on weight. Hereinafter, the ratio (%) based on weight will be noted as “wt %”.

On calculation, the impurity concentration can be reduced whatever range the formation ratio of the solidified layer 4 is in. However, when the formation ratio of the solidified layer 4 relative to the initial raw material is 10 wt % or more, a longer single crystal 6 can be grown while reducing impurities.

Furthermore, when the formation ratio of the solidified layer 4 relative to the initial raw material is 99 wt % or less, the effect of reducing impurities is further raised, while at the same time, the formation ratio of the solidified layer can be controlled more simply, conveniently, and accurately, and the amount of melt to be removed can be more precise.

Furthermore, in the second step, the formation ratio of the solidified layer 4 is preferably detected by the change in melt level attributable to the difference in densities of solid and liquid. In this manner, it becomes possible to grasp and control the formation ratio of the solidified layer more simply, conveniently, and accurately.

When silicon changes from liquid to solid, the density becomes about 0.91 times as much. That is, the volume becomes about 1.1 times as much. Therefore, regarding the liquid level (which will be referred to as “initial raw material level”) when the initially loaded raw material is melted, as the formed amount of the solidified layer 4 increases, the total volume of the solidified layer 4 and the melt 3 put together also expands owing to the volume expansion caused by the formation of the solidified layer 4. Thus, the liquid level as seen from the surface rises above the initial raw material level. Note that the change in melt level is measured by, for example, a known technique disclosed in JP 2008-195545 A to measure the liquid level. The solidified amount formed inside can be estimated based on the liquid level.

Next, as shown in FIG. 1 (d) to FIG. 1 (e), at least a part of the melt 3 is removed in a state where the solidified layer 4 and the melt 3 coexist. This step will be referred to as a third step (S03 in FIG. 2). A state where the solidified layer 4 is formed up to a certain proportion is a state where the solidified layer 4 having a low impurity concentration and the melt 3 having a high impurity concentration coexist owing to segregation. By removing at least a part of the melt 3 having a high impurity concentration in this state, the average impurity concentration in the crucible 1 can be lowered. From the viewpoint of impurity reduction, it is desirable to remove all the melt 3, but only removing a part produces a sufficient effect of impurity reduction.

When at least a part of the melt 3 is removed in the third step, it is desirable to remove the melt 3 by suction by using a suction apparatus 5 equipped with a nozzle. As a method for removing the melt 3 from the state where the solidified layer 4 and the melt 3 coexist, in the field of refinement or the like, for example, discharging of the liquid by tilting the container is widely performed, and it is also possible to remove the melt 3 by a similar method in the present invention. However, if the melt 3 is to be removed by suction by using a suction apparatus 5 equipped with a nozzle, there is no need to provide a complex facility such as a tilting mechanism of the crucible 1, and the melt 3 can be removed more simply and conveniently.

Incidentally, the method for removing the melt 3 by suction by using a suction apparatus 5 equipped with a nozzle is known technology as disclosed in JP H6-72792 A and JP 2018-70426 A. By making a container with a suction nozzle protruding downwards come into contact with the melt 3, and for example, using the difference in the pressure inside the container and the pressure inside the CZ pulling apparatus, the melt 3 can be suctioned at once. In this event, since the suction nozzle comes into contact with the melt 3, the suction nozzle preferably has heat resistance and high purity. The suction nozzle is preferably selected from quartz material, ceramics material, carbon material, and high-melting-point metal material, for example.

Next, as shown in FIG. 1 (f), the solidified layer 4 is re-melted. This step will be referred to as a fourth step (S04 in FIG. 2). When a melt 3′ is obtained by re-melting the solidified layer 4 after removing the melt 3 having a high impurity concentration or the part of the unremoved melt 3 and the solidified layer 4, a melt 3′ having a low impurity concentration compared with the initial melt 3 can be obtained owing to having the melt 3 with the high impurity concentration removed.

Lastly, as shown in FIG. 1 (g) to FIG. 1 (h), a seed crystal is brought into contact with the melt 3′ obtained in the fourth step, then a single crystal 6 is grown by pulling. This step will be referred to as a fifth step (S05 in FIG. 2). In this way, it is possible to obtain a single crystal 6 with an extremely low impurity concentration compared with a case where a single crystal 6 is grown from the initial melt 3.

In single crystal growth according to a normal CZ method, segregation occurs when pulling a single crystal from the melt, and therefore, a single crystal with a lower impurity concentration than the melt can be obtained as explained above. In the present invention, the silicon raw material of the solidified layer is purified by making use of the segregation phenomenon caused by solidifying a part of the melt in the crucible 1. Therefore, this means that a double segregation is occurring as the entire pulling process of the CZ method, and a single crystal with an extremely high purity can be obtained.

A silicon raw material 2 to use in the present invention is preferably a semiconductor-grade high-purity raw material. The effect of reducing impurities can be achieved using a raw material of any grade, but the obtained single crystal can be purified even more the higher the purity of the raw material used at the beginning. Therefore, using a semiconductor-grade high-purity raw material having the highest purity is preferable since a single crystal with a higher purity can be grown.

### Second Embodiment

In the above-described first embodiment, the amount of the silicon raw material in the crucible is less than the amount at the initial loading since at least a part of the melt 3 is removed. As a result, the length of the single crystal that can be grown becomes short (the yield is reduced).

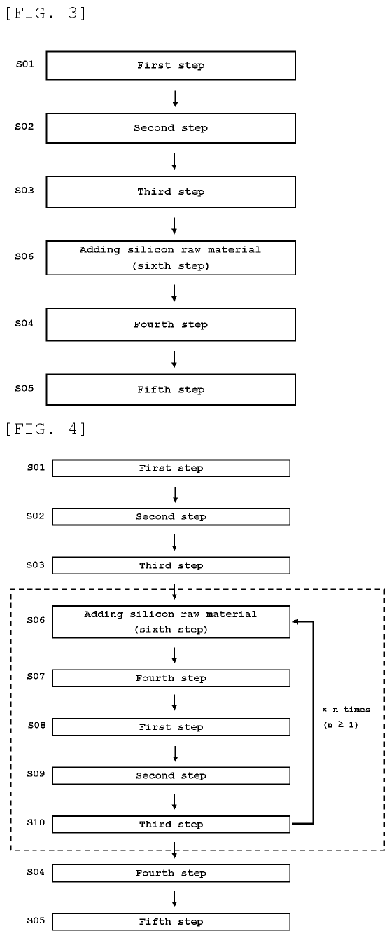

Accordingly, in the present embodiment, a step of adding a silicon raw material in the crucible is performed after the third step of removing at least a part of the melt in order to prevent decrease in the length of the single crystal that can be grown. Points different from the first embodiment will be mainly described with reference to FIG. 3. The “sixth step” (S06 in FIG. 3) in FIG. 3 is the point that differs from the first embodiment.

Specifically, as a sixth step (S06 in FIG. 3), a silicon raw material 2 is added into the crucible 1 after the above-described third step (FIG. 1 (d) to FIG. 1 (e) and S03 in FIG. 3) and before the fourth step (FIG. 1 (f) and S04 in FIG. 3). In this manner, the effect of reducing impurities can be achieved while maintaining the length of the single crystal that can be grown.

Note that the amount of the silicon raw material 2 added in the sixth step is not particularly limited, and may be similar to the amount of the melt 3 removed in the third step immediately before, or the amount may be more, or the amount may be less, and the effect of reducing impurities can still be achieved while maintaining the length of the single crystal that can be grown. The amount of the silicon raw material 2 to be added can be determined according to the desired impurity concentration in the single crystal and length of the single crystal.

### Third Embodiment

For further purification, it is desirable to increase the number of times the impurity reduction using segregation is performed. For this purpose, performing additional steps with the above-described first embodiment is also effective. Points different from the first embodiment will be mainly described with reference to FIG. 4. In FIG. 4, the steps surrounded by the dotted lines are the points that differ from the first embodiment.

Specifically, after the above-described third step (FIG. 1 (d) to FIG. 1 (e) and S03 in FIG. 4) and before the fourth step (FIG. 1 (f) and S04 in FIG. 4), a silicon raw material 2 is added into the crucible 1 as a sixth step (S06 in FIG. 4), and subsequently, the fourth step (S07 in FIG. 4), the first step (S08 in FIG. 4), the second step (S09 in FIG. 4), and the third step (S10 in FIG. 4) are performed once or more (noted as n≥1 in FIG. 4) in this order. That is, this may be repeated twice or more. In this way, the number of times segregation occurs can be increased. Note that the amount of the silicon raw material 2 added in the sixth step is not particularly limited, and may be similar to the amount of the melt 3 removed in the third step immediately before, or the amount may be more, or the amount may be less, and the effect of reducing impurities can still be achieved.

In addition, in the fourth step (S07 in FIG. 4) and the first step (S08 in FIG. 4) in the additional steps, the melting conditions may be the same or different. Since the same type of material (silicon) is melted, the fourth step (S07 in FIG. 4) and the first step (S08 in FIG. 4) in the additional steps can also progress at the same time.

Furthermore, the second embodiment and the third embodiment can also be combined. It is also effective to perform the steps surrounded by the dotted lines in FIG. 4 once or more as in the third embodiment, then perform the sixth step (S06) of adding the silicon raw material described in the second embodiment following the last third step (S10), and subsequently form a melt inside the crucible, and grow a single crystal. In this manner, a single crystal with a lower impurity concentration can be grown without lowering the yield.

Next, before describing the experimental results of single crystal growth, results of studying the effect of reducing impurities by calculation will be described. Here, the carbon concentration in a single crystal 6 in a case where a 26-inch crucible (quartz crucible with an outer diameter of about 660 mm) is used and 200 kg of polycrystalline silicon is loaded was considered. It goes without saying that regarding impurities other than carbon such as heavy metal, a reduction effect can also be achieved regarding those with a segregation coefficient “k” that is less than 1.

Usually, impurity carbon relating to the silicon raw material 2 (polycrystalline silicon) includes carbon contained in the silicon raw material 2 and carbon adhered to the surface of the silicon raw material 2. The concentration (amount) of carbon contained in the silicon raw material 2 varies depending on the manufacturer, for example. In addition, the concentration (amount) of carbon adhered to the surface of the silicon raw material 2 varies depending on handling method such as whether or not cleaning is performed, in addition to the difference in manufacturer.

Generally, it is not easy to separate the amount contained inside the raw material and the amount adhered to the surface, and therefore, in the present study, the total amount of the two will be noted as the carbon concentration of the silicon raw material 2. Polycrystalline silicon of various carbon concentrations can be acquired depending on the difference in manufacturer or handling method as described above.

In addition, measurement of carbon concentration in a crystal is usually performed by an FT-IR method, and the lower detection limit of carbon concentration in an FT-IR method is about 0.01 ppma (=5×10¹⁴ atoms/cm³) in the present condition, even with improvements in the number of times the measurement is performed and the reference, etc.

Accordingly, in the present study, it was assumed that a silicon raw material 2 with a carbon concentration level that can be detected with certainty by the current carbon concentration evaluation method was used as the raw material in order to clearly evaluate and inspect the effect of the present invention to reduce carbon concentration. Thus, it was decided that the study would be conducted using a silicon raw material 2 with a carbon concentration of 0.07 ppma (=3.5×10¹⁵ atoms/cm³). Note that an equivalent silicon raw material 2 was also used in the Example and Comparative Example described below.

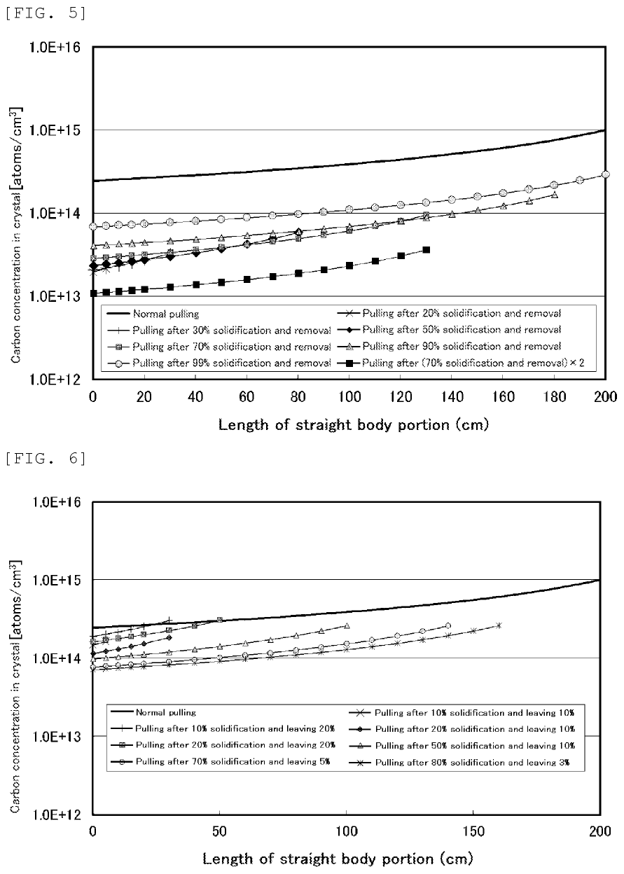

Firstly, regarding the pulling conditions of a conventional CZ method, calculations were made regarding a case where 200 kg of polycrystalline silicon with a carbon concentration of 0.07 ppma was melted as the silicon raw material 2, and a silicon single crystal 6 with a product diameter of 200 mm was grown with a target diameter of 206 mm. It was assumed that an enlarged-diameter portion was formed, a straight body portion was formed from where the diameter reached the target, and when the length of the straight body portion was about 200 cm and the solidification ratio was about 0.78, diameter decrease was started to form a rounded portion. The calculated value of the carbon concentration in the crystal in this case is as shown in FIG. 5 as “normal pulling”.

In addition, the carbon concentration in a crystal was calculated regarding a case where a silicon single crystal 6 was grown adopting the technique for reducing impurities according to the present invention, that is, a case where a certain proportion of a solidified layer 4 was formed, and after removing all the melt 3 from that state, the solidified layer 4 was re-melted and the silicon single crystal 6 was pulled. As shown in FIG. 5 as “pulling after X % solidification and removal” (X=20, 30, 50, 70, 90, and 99), in the cases where the certain proportions of the solidified layer 4 were 20 wt %, 30 wt %, 50 wt %, 70 wt %, 90 wt %, and 99 wt % relative to the initially loaded raw material, the calculation results were that crystals with notably low carbon concentrations compared with “normal pulling” can be obtained. Furthermore, the calculation results showed that the lower the solidification ratio, the lower the carbon concentration of the grown single crystal.

Furthermore, the calculated value of the carbon concentration in a case where 70 wt % relative to the initially loaded raw material was solidified, the melt 3 was removed, then the same amount as the removed melt 3, 30 wt %, of additional raw material was introduced, 70 wt % was solidified once more, the melt 3 was removed, then the solidified layer 4 was re-melted, and a crystal was pulled is shown as “pulling after (70% solidification and removal)×2”. As clearly seen from FIG. 5, the calculation results were that a single crystal with an even lower concentration of impurity carbon can be expected to be obtained compared with “pulling after 70% solidification and removal” where no additional raw material is introduced.

On the other hand, as the solidification ratio becomes lower, the amount of the melt that is totally removed increases, and therefore, the raw material that can be used to grow a single crystal becomes less. As a result, the length of the grown silicon single crystal 6 becomes shorter.

Accordingly, the calculation results of the carbon concentration in a silicon single crystal 6 in a case where only a part of the melt 3 is removed, instead of removing all the remaining melt 3 when the solidified layer 4 is formed is shown in FIG. 6.

The notation in FIG. 6 saying “pulling after 10% solidification and leaving 10%” indicates a case where 10 wt % of a solidified layer 4 is formed relative to the initially loaded raw material, 80 wt % out of the remaining 90 wt % of the melt 3 is removed, leaving 10 wt % of the melt 3, re-melting the 10 wt % of the solidified layer 4 and the 10 wt % of the melt 3, and then a silicon single crystal 6 is grown. Besides this case, cases of “pulling after 10% solidification and leaving 20%”, “pulling after 20% solidification and leaving 10%”, “pulling after 20% solidification and leaving 20%”, “pulling after 50% solidification and leaving 10%”, “pulling after 70% solidification and leaving 5%”, and “pulling after 80% solidification and leaving 3%” are shown in FIG. 6.

For example, as clearly shown by the comparison of “pulling after 20% solidification and leaving 10%” and “pulling after 20% solidification and leaving 20%” in FIG. 6, it is revealed that when the suctioned amount (removed amount) of the melt 3 is large, the carbon concentration in the crystal is low compared to when the suctioned amount (removed amount) of the melt 3 is small, but the length of the silicon single crystal 6 that can be grown becomes short.

Note that the selection of the solidified amount and the suctioned amount (removed amount) can be appropriately set according to the target carbon concentration and yield (length of the single crystal).

### Example

Hereinafter, the present invention will be described in detail with reference to an Example. However, the present invention is not limited thereto.

### Example

An experiment was conducted, adopting the same conditions as in the above study by calculation. Specifically, using a CZ pulling apparatus, 200 kg of polycrystalline silicon with a carbon concentration of 0.07 ppma was loaded in a 26-inch crucible as a silicon raw material, and was melted. As the CZ pulling apparatus, a CZ pulling apparatus equipped with a resistance heating heater divided into two upper and lower stages with almost the same diameter around the crucible was used, and when forming a solidified layer, the electric power and position of the lower-stage heater were manipulated to form the solidified layer from the bottom of the crucible.

In this event, the formation ratio of the solidified layer was measured by detecting the change in melt level attributable to the difference in the densities of solid and liquid. After forming the solidified layer until the liquid level reached the level corresponding to a case where 80 wt % of solidified layer has been formed, about 17 wt % (=34 kg) of the melt was suctioned out by a suction apparatus equipped with a nozzle made of a high-purity quartz in a state where the solidified layer and the melt coexist.

Subsequently, the solidified layer was melted, an enlarged-diameter portion was formed, a straight body portion was formed from where the diameter reached the target of 206 mm, and a crystal having a straight body portion with a length of about 160 cm was grown. Samples of this crystal were taken by cutting the crystal into round slices from the end portion of the straight body portion just before going into the rounded portion, and the carbon concentration was measured by an FT-IR method. In this event, improvements were made in the number of times the measurement was performed and the reference, etc., and an FT-IR measurement apparatus with the value of the lower detection limit improved to about 0.01 ppma (=5×10¹⁴ atoms/cm³) was used.

As a result, the concentration of the impurity carbon was below the value of the detection limit.

Therefore, to estimate the carbon concentration, measurement was performed by a different measurement method. Specifically, a method of irradiating the samples with an electron beam and measuring a carbon-related peak by a PL method was adopted. Since the peak intensity depends not only on carbon concentration but also on oxygen concentration in the PL method, the method cannot be said to be completely established as an evaluation method, but an estimation to a certain degree is possible. Note that the value of the lower detection limit of carbon concentration in the PL method is reported to be about 1×10¹³ atoms/cm³.

When the carbon concentration was measured by this PL method, the carbon concentration was 3.5×10¹⁴ atoms/cm³ according to an estimation based on a calibration curve created in one's company.

The results were a little higher than the values expected from the calculation results (“pulling after 80% solidification and leaving 3%” in FIG. 6). It can be considered that this may be due to contamination caused by the suction operation of the melt or the like, or variation in the carbon concentration of the polycrystalline silicon used as the raw material, etc.

### Comparative Example

Using the same pulling apparatus as in the Example, 200 kg of polycrystalline silicon with a carbon concentration of 0.07 ppma was loaded in a crucible as a silicon raw material and all the material was melted. Subsequently, an enlarged-diameter portion was formed, a straight body portion was formed from where the diameter reached the target of 206 mm, and a crystal having a straight body portion with a length of about 200 cm was grown. Samples of this crystal were taken by cutting the crystal into round slices from the end portion of the straight body portion just before going into the rounded portion, and the carbon concentration was measured by the same FT-IR method as in the Example.

As a result, carbon was even detected by the FT-IR method in the Comparative Example, and the concentration of the impurity carbon was 0.02 ppma.

In addition, when the samples were irradiated with an electron beam and a carbon-related peak was measured by the PL method in the same manner as in the Example in order to compare with the Example, the result was 1.1×10¹⁵ atoms/cm³.

Comparing the Example and the Comparative Example, the carbon concentration in the crystal in the Example was not more than the detection limit (0.01 ppma), but the carbon concentration in the Comparative Example was 0.02 ppma according to a measurement by an ordinary FT-IR method as described above.

Furthermore, from the results of irradiating the samples with an electron beam and measuring the carbon-related peak by the PL method, it was estimated that the crystal obtained in the Comparative Example had nearly 3 times the carbon concentration of the crystal obtained in the Example.

It was revealed that according to the inventive method for growing a single crystal, a crystal with a remarkably low impurity concentration can be obtained, compared to what was conventional.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1-7. (canceled)

8. A method for growing a single crystal according to a Czochralski method (CZ method) or a magnetic field applied CZ method (MCZ method), the method comprising:
a first step of obtaining a melt by melting a silicon raw material loaded in a crucible;
a second step of forming a solidified layer by solidifying a part of the melt;
a third step of removing at least a part of the melt in a state where the solidified layer and the melt coexist;
a fourth step of obtaining a melt by melting the solidified layer; and
a fifth step of growing a silicon single crystal from the melt.

9. The method for growing a single crystal according to claim 8, wherein a sixth step of adding a silicon raw material into the crucible is performed after the third step and before the fourth step.

10. The method for growing a single crystal according to claim 8, wherein after the third step and before the fourth step,
a sixth step of adding a silicon raw material into the crucible,
the fourth step,
the first step,
the second step, and
the third step are performed once or more in this order.

11. The method for growing a single crystal according to claim 8, wherein a formation ratio of the solidified layer in the second step is 10% or more to 99% or less based on weight relative to the raw material initially loaded in the first step.

12. The method for growing a single crystal according to claim 9, wherein a formation ratio of the solidified layer in the second step is 10% or more to 99% or less based on weight relative to the raw material initially loaded in the first step.

13. The method for growing a single crystal according to claim 10, wherein a formation ratio of the solidified layer in the second step is 10% or more to 99% or less based on weight relative to the raw material initially loaded in the first step.

14. The method for growing a single crystal according to claim 8, wherein in the third step, the melt of silicon is removed by suction by using a suction apparatus equipped with a nozzle.

15. The method for growing a single crystal according to claim 9, wherein in the third step, the melt of silicon is removed by suction by using a suction apparatus equipped with a nozzle.

16. The method for growing a single crystal according to claim 10, wherein in the third step, the melt of silicon is removed by suction by using a suction apparatus equipped with a nozzle.

17. The method for growing a single crystal according to claim 11, wherein in the third step, the melt of silicon is removed by suction by using a suction apparatus equipped with a nozzle.

18. The method for growing a single crystal according to claim 12, wherein in the third step, the melt of silicon is removed by suction by using a suction apparatus equipped with a nozzle.

19. The method for growing a single crystal according to claim 13, wherein in the third step, the melt of silicon is removed by suction by using a suction apparatus equipped with a nozzle.

20. The method for growing a single crystal according to claim 8, wherein in the second step, a formation ratio of the solidified layer is detected by a change in melt level attributable to a difference in densities of solid and liquid.

21. The method for growing a single crystal according to claim 8, wherein a semiconductor-grade high-purity raw material is used as the silicon raw material.
